(19) United States
(12) Patent Application Publication
(10) Pub. No.: US 2025/0126943 A1
(43) Pub. Date: Apr. 17, 2025

(54) STRETCHABLE DISPLAY BASED ON MICRO-LED AND METHOD OF MANUFACTURING THE SAME

(71) Applicant: UNIVERSITY-INDUSTRY COOPERATION GROUP OF KYUNG HEE UNIVERSITY, Yongin-si (KR)

(72) Inventors: Jin JANG, Seoul (KR); Chan Ju PARK, Goyang-si (KR)

(73) Assignee: UNIVERSITY-INDUSTRY COOPERATION GROUP OF KYUNG HEE UNIVERSITY, Yongin-si (KR)

(21) Appl. No.: 18/734,747

(22) Filed: Jun. 5, 2024

(30) Foreign Application Priority Data
Oct. 17, 2023 (KR) 10-2023-0138712

(51) Int. Cl. H01L 33/62; H01L 25/16

(52) U.S. Cl. CPC H10H 20/857; H01L 25/167; H10H 20/0364

(57) ABSTRACT

The present disclosure relates to a stretchable display and a method of manufacturing the same. The stretchable display according to one embodiment includes a stretchable substrate; a plurality of pixel islands formed on the stretchable substrate, wherein each of the pixel islands includes at least one thin-film transistor and one micro-LED; a plurality of pixel wires formed based on a liquid metal and connecting adjacent pixel islands among the pixel islands to each other; and a plurality of bus wires formed based on the liquid metal and connected to at least one pixel island among the pixel islands.

### CROSS-REFERENCE TO RELATED APPLICATION

This application claims priority to Korean Patent Application No. 10-2023-0138712, filed on Oct. 17, 2023, in the Korean Intellectual Property Office, the disclosure of which is incorporated herein by reference.

### BACKGROUND OF THE DISCLOSURE

### Field of the Disclosure

The present disclosure relates to a stretchable display, and more particularly, to a technical idea for implementing the pixel array of a stretchable display based on a flip-chip micro-LED and a thin-film transistor.

### Description of the Related Art

Recently, various technologies for implementing stretchable electronic elements applied to electronic skin, specifically technologies related to soft robotics and stretchable displays, have received much attention.

Stretchable elements have the advantage of being able to be attached to an object regardless of the surface roughness of the object. To implement stretchable electronic devices, mechanical stability and stretchable wiring connections must be considered.

Specifically, to improve mechanical stability, elements such as transistors, sensors, and diodes that constitute a stretchable electronic device must maintain the electrical characteristics thereof even when stretched. Accordingly, research on robust island structures is continuing to achieve stable electrical performance when the element is stretched.

Previously, as shown in drawing number 100 of FIG. 1, a method of applying a winding-shaped wiring pattern for stretchable interconnection was proposed. Wiring formed by the above method is vulnerable to deformation due to external force, and there is a problem that cracks and damage to the wiring may occur due to deformation.

### RELATED ART DOCUMENTS

### Patent Documents

(Patent Document 1) Japanese Patent Application Publication No. 10-2020-177988, “THIN-FILM TRANSISTOR ARRAY SUBSTRATE, SUBSTRATE FOR ELECTRONIC DEVICES, AND METHOD OF MANUFACTURING THIN-FILM TRANSISTOR ARRAY SUBSTRATE AND SUBSTRATE FOR ELECTRONIC DEVICES”
(Patent Document 2) Korean Patent No. 10-2528403, “STRETCHABLE ELECTRONIC DEVICE AND METHOD OF MANUFACTURING THE SAME”

### SUMMARY OF THE DISCLOSURE

Therefore, the present disclosure has been made in view of the above problems, and it is an object of the present disclosure to provide a stretchable display capable of minimizing the occurrence of cracks and damage due to deformation of wiring by applying a stretchable wire based on a liquid metal that is not curved and a method of manufacturing the stretchable display.

It is another object of the present disclosure to provide a stretchable display capable of securing excellent electrical characteristics by integrating pixel islands and liquid metal-based wires on a stretchable substrate and a method of manufacturing the stretchable display.

It is yet another object of the present disclosure to provide a stretchable display capable of minimizing an area and ensuring operational stability by replacing a capacitor provided in each pixel island with a ferroelectric thin-film transistor and a method of manufacturing the stretchable display.

In accordance with one aspect of the present disclosure, provided is a stretchable display including a stretchable substrate; a plurality of pixel islands formed on the stretchable substrate, wherein each of the pixel islands includes at least one thin-film transistor and one micro-LED; a plurality of pixel wires formed based on a liquid metal and connecting adjacent pixel islands among the pixel islands to each other; and a plurality of bus wires formed based on the liquid metal and connected to at least one pixel island among the pixel islands.

According to one aspect, each of the bus wires may be connected to the at least one pixel island through one end thereof and may be connected to a pixel driving circuit through the other end thereof.

According to one aspect, in each of the pixel islands, the thin-film transistor and the micro-LED may be bonded through solder and flux formed on the thin-film transistor.

According to one aspect, the pixel islands may be formed on the stretchable substrate based on a transfer process and a laser cutting process using a stamp for the thin-film transistor and micro-LED formed on a flexible substrate.

According to one aspect, the pixel wires and the bus wires may be formed on the stretchable substrate through a lift-off process based on negative PR.

According to one aspect, each of the pixel islands may include two thin-film transistors and one ferroelectric thin-film transistor.

In accordance with another aspect of the present disclosure, provided is a method of manufacturing a stretchable display, the method including transferring a plurality of pixel islands each including at least one thin-film transistor and one micro-LED onto a stretchable substrate; applying negative PR onto a preset area of the stretchable substrate where the pixel islands have been transferred; applying a liquid metal onto the stretchable substrate coated with the negative PR; and removing the negative PR to form a plurality of pixel wires connecting adjacent pixel islands among the pixel islands to each other and a plurality of bus wires connected to at least one pixel island among the pixel islands.

According to one aspect, the transferring may further include forming an LED-TFT structure including a flexible substrate, the thin-film transistor, and the micro-LED on a carrier substrate; attaching a polymer stamp to an upper portion of the LED-TFT structure and separating the LED-TFT structure from the carrier substrate; forming the pixel islands by performing a laser cutting process on the LED-TFT structure attached to the polymer stamp; and transferring the pixel islands attached to the polymer stamp onto the stretchable substrate.

According to one aspect, the forming of the LED-TFT structure may further include depositing solder on the thin-film transistor; coating the solder-deposited thin-film transistor with flux; bonding the micro-LED; removing the flux; and forming a passivation layer.

According to one aspect, the transferring may further include treating the stretchable substrate with ultraviolet rays (UV) and ozone (O₃); and transferring the pixel islands onto the stretchable substrate treated with ultraviolet rays (UV) and ozone (O₃).

According to one aspect, in the applying of the liquid metal, after treating the stretchable substrate coated with the negative PR with oxygen (O₂) plasma, the liquid metal may be applied.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a diagram explaining a conventional stretchable display;

FIG. 2 is a diagram explaining a stretchable display according to one embodiment;

FIG. 3 is a flowchart explaining a method of manufacturing a stretchable display according to one embodiment;

FIGS. 4A to 4H are diagrams explaining the method of manufacturing a stretchable display according to one embodiment in more detail;

FIGS. 5A to 5D are diagrams explaining a method of forming an LED-TFT structure in the method of manufacturing a stretchable display according to one embodiment in more detail;

FIG. 6 is a diagram explaining the structural features of the micro-LED element of the stretchable display according to one embodiment in more detail;

FIG. 7 includes diagrams explaining an ozone (O₃) treatment method in the method of manufacturing a stretchable display according to one embodiment in more detail;

FIG. 8 includes diagrams explaining an oxygen (O₂) plasma treatment method in the method of manufacturing a stretchable display according to one embodiment in more detail;

FIGS. 9A-9M include diagrams explaining the performance experiment results of the thin-film transistor and micro-LED of the stretchable display according to one embodiment;

FIGS. 10A-10J include diagrams explaining the pixel performance experiment results of the stretchable display according to one embodiment; and

FIGS. 11A-11N include diagrams explaining the experimental results of changes in electrical characteristics depending on the shapes of the liquid metal-based wire and pixel island of the stretchable display according to one embodiment.

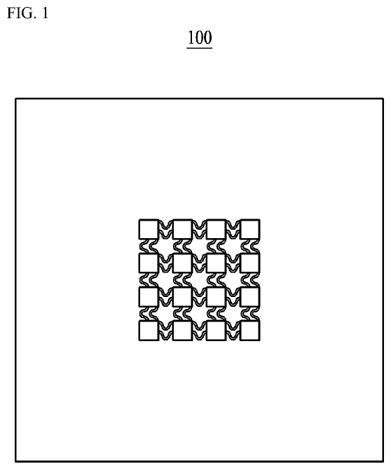

### DETAILED DESCRIPTION OF THE DISCLOSURE

Specific structural and functional descriptions of embodiments according to the concept of the present disclosure disclosed herein are merely illustrative for the purpose of explaining the embodiments according to the concept of the present disclosure. Furthermore, the embodiments according to the concept of the present disclosure can be implemented in various forms and the present disclosure is not limited to the embodiments described herein.

The embodiments according to the concept of the present disclosure may be implemented in various forms as various modifications may be made. The embodiments will be described in detail herein with reference to the drawings. However, it should be understood that the present disclosure is not limited to the embodiments according to the concept of the present disclosure, but includes changes, equivalents, or alternatives falling within the spirit and scope of the present disclosure.

The terms such as “first” and “second” are used herein merely to describe a variety of constituent elements, but the constituent elements are not limited by the terms. The terms are used only for the purpose of distinguishing one constituent element from another constituent element. For example, a first element may be termed a second element and a second element may be termed a first element without departing from the teachings of the present disclosure.

It should be understood that when an element is referred to as being “connected to” or “coupled to” another element, the element may be directly connected or coupled to the other element or intervening elements may be present. In contrast, when an element is referred to as being “directly connected to” or “directly coupled to” another element, there are no intervening elements present. Other words used to describe the relationship between elements or layers should be interpreted in a like fashion (e.g., “between,” versus “directly between,” “adjacent,” versus “directly adjacent,” etc.).

The terms used in the present specification are used to explain a specific exemplary embodiment and not to limit the present inventive concept. Thus, the expression of singularity in the present specification includes the expression of plurality unless clearly specified otherwise in context. Also, terms such as “include” or “comprise” should be construed as denoting that a certain characteristic, number, step, operation, constituent element, component or a combination thereof exists and not as excluding the existence of or a possibility of an addition of one or more other characteristics, numbers, steps, operations, constituent elements, components or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, preferred embodiments of the present disclosure will be described in detail with reference to the accompanying drawings. However, the scope of the present disclosure is not limited by these embodiments. Like reference numerals in the drawings denote like elements.

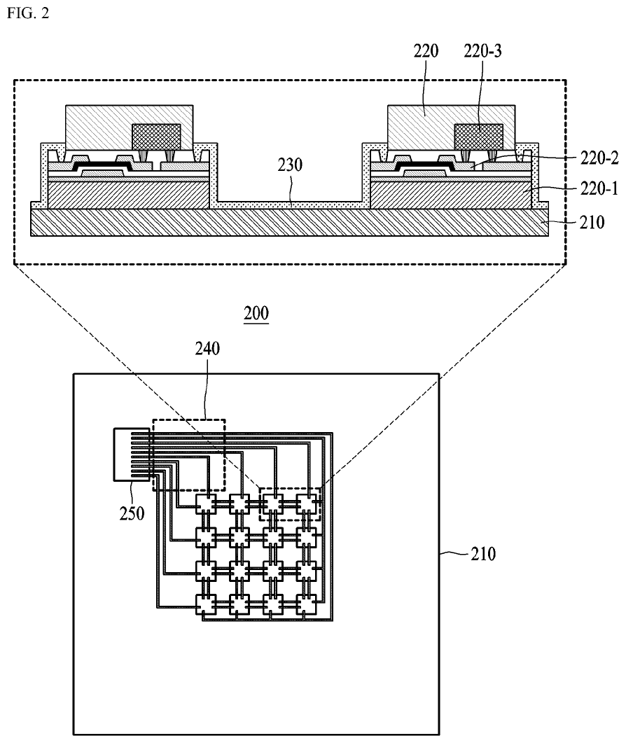

FIG. 2 is a diagram explaining a stretchable display according to one embodiment.

Referring to FIG. 2, a stretchable display 200 according to one embodiment may minimize the occurrence of cracks and damage due to deformation of wiring by applying a stretchable wire based on a liquid metal that is not curved.

In addition, the stretchable display 200 may secure excellent electrical characteristics by integrating pixel islands and liquid metal-based wires on a stretchable substrate.

In addition, the stretchable display 200 may minimize an area and ensure operational stability by replacing a capacitor provided in each pixel island with a ferroelectric thin-film transistor.

The stretchable display 200 may include a stretchable substrate 210, a plurality of pixel islands 220, a plurality of pixel wires 230, and a plurality of bus wires 240.

The pixel islands 220 according to one embodiment may be formed on the stretchable substrate 210, and each of the pixel islands 220 may include at least one thin-film transistor 220-2 and one micro-LED 220-3.

For example, the stretchable substrate 210 may be a polydimethylsiloxane (PDMS) substrate.

In addition, 16 pixel islands 220 may be implemented to form a 4×4 pixel array. However, the number of the pixel islands 220 according to one embodiment is not limited thereto, and 15 or less or 17 or more pixel islands 220 may be implemented.

According to one aspect, each of the pixel islands 220 may further include a flexible substrate 220-1, the thin-film transistor 220-2, a micro-LED 240, and a passivation layer surrounding the micro-LED 240. For example, the flexible substrate 220-1 may be a polyimide (PI) substrate, and the passivation layer may be SU-8.

Each of the pixel islands 220 may include two thin-film transistors (i.e., switching TFT and driving TFT) and one capacitor (i.e., 2TFT+capacitor structure). Preferably, each of the pixel islands 220 may include two thin-film transistors (i.e., switching TFT and reset TFT) and one ferroelectric thin-film transistor (FeTFT) for driving (i.e., 2TFT+1FeTFT structure)

For example, the ferroelectric thin-film transistor (FeTFT) may include a ferroelectric material based on zirconium (Zr). As a more specific example, the ferroelectric thin-film transistor (FeTFT) may include at least one ferroelectric material of HfZrO, ZrAlO, and ZrO.

Specifically, when a thin-film transistor and a capacitor are implemented on a flexible/stretchable substrate, depending on bending (tensile) strain, there is a risk that a capacitor of a metal-insulator-metal (MIM) structure with a large area may be broken. When the capacitor is broken, a short/open circuit may occur between electrodes, making a display impossible to operate.

According to the present disclosure, a capacitor in the pixel islands 220 may be replaced with a ferroelectric thin-film transistor (FeTFT), which may simultaneously perform the roles of a thin-film transistor and a capacitor. In this case, operational stability and reliability may be secured by minimizing an area and preventing the occurrence of short/open circuits.

According to one aspect, in each of the pixel islands 220, the thin-film transistor 220-2 and the micro-LED 220-3 may be joined to each other through solder and flux formed on the thin-film transistor 220-2.

For example, the solder may be formed at a position corresponding to at least one of the source electrode and drain electrode of the thin-film transistor 220-2, so that the source electrode or drain electrode of the thin-film transistor 220-2 is electrically connected to at least one of the n-type electrode and p-type electrode of the micro-LED 220-3.

According to one aspect, the pixel islands 220 may formed on the stretchable substrate 210 based on a stamp-using transfer process and a laser cutting process for the thin-film transistor 220-2 and the micro-LED 220-3 formed on the flexible substrate 220-1.

The pixel wires 230 according to one embodiment may be formed based on a liquid metal, and may connect adjacent pixel islands among the pixel islands 220.

In addition, the bus wires 240 may be formed based on a liquid metal on the stretchable substrate 210, and may be connected to at least one pixel island of the pixel islands 220.

For example, the liquid metal may include at least one of galinstan, gallium, gallium alloy, tin, tin alloy, indium, indium alloy, indium-tin (In—Sn) alloy, lead, lead alloy, and indium-tin (In—Sn) alloy, but the present disclosure is not limited thereto.

According to one aspect, each of the bus wires 240 may be connected to at least one pixel island through one end thereof, and may be connected to a pixel driving circuit 250 through the other end thereof.

For example, the bus wires 240 may connect each of the 12 pixel islands placed on the outside of the pixel islands 220 that make up a 4×4 pixel array to the pixel driving circuit 250.

According to one aspect, the pixel wires 230 and the bus wires 240 may be formed on the stretchable substrate 210 through a lift-off process based on negative PR.

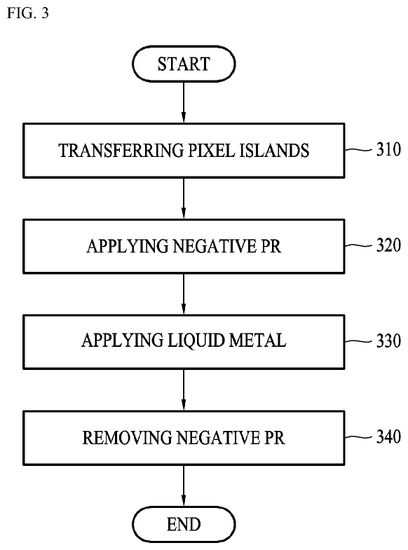

FIG. 3 is a flowchart explaining a method of manufacturing a stretchable display according to one embodiment.

Referring to FIG. 3, according to the manufacturing method, in step 310, a plurality of pixel islands each including at least one thin-film transistor and one micro-LED may be transferred onto a stretchable substrate.

According to one aspect, according to the manufacturing method, in step 310, an LED-TFT structure including a flexible substrate, a thin-film transistor, and a micro-LED may be formed on a carrier substrate, a polymer stamp may be attached to the upper portion of the LED-TFT structure, and then the LED-TFT structure may be separated from the carrier substrate.

In addition, according to the manufacturing method, in step 310, a plurality of pixel islands may be formed through a laser cutting process for the LED-TFT structure attached to the polymer stamp, and then the pixel islands attached to the polymer stamp may be transferred onto the stretchable substrate.

Specifically, according to the manufacturing method, in step 310, after forming a coating layer based on carbon nanotubes (CNTs) and graphene oxide on the carrier substrate, a flexible substrate may be bonded onto the coating layer.

In addition, according to the manufacturing method, in step 310, solder may be deposited on the thin-film transistor, the solder-deposited thin-film transistor may be coated with flux, the micro-LED may be bonded to the thin-film transistor, the flux may be removed, and then a passivation layer may be formed to form an LED-TFT structure.

According to one aspect, according to the manufacturing method, in step 310, after treating a stretchable substrate with ultraviolet rays (UV) and ozone (O₃), a plurality of pixel islands may be transferred onto the ultraviolet rays (UV)-and ozone (O₃)-treated stretchable substrate.

Specifically, according to the manufacturing method, in step 310, by performing UV/O₃ plasma treatment on the stretchable substrate for 1 to 5 minutes, the adhesion between the stretchable substrate and the flexible substrate may be increased.

Next, according to the manufacturing method, in step 320, negative PR may be applied onto a preset area of the stretchable substrate where the pixel islands have been transferred.

Next, according to the manufacturing method, in step 330, a liquid metal may be applied onto the stretchable substrate coated with the negative PR.

According to one aspect, according to the manufacturing method, in step 330, after oxygen (O₂) plasma treatment of the stretchable substrate coated with the negative PR, the liquid metal may be applied onto the stretchable substrate.

For example, according to the manufacturing method, in step 320, after performing first oxygen (O₂) plasma treatment on the stretchable substrate, application of the negative PR may be performed. According to the method, in step 330, after performing second oxygen (O₂) plasma treatment on the stretchable substrate coated with the negative PR, application of the liquid metal may be performed.

Next, according to the manufacturing method, in step 340, the negative PR may be removed to form a plurality of pixel wires connecting adjacent pixel islands of a plurality of pixel islands and a plurality of bus wires connected to at least one pixel island of the pixel islands.

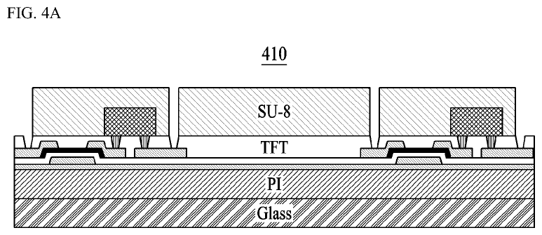

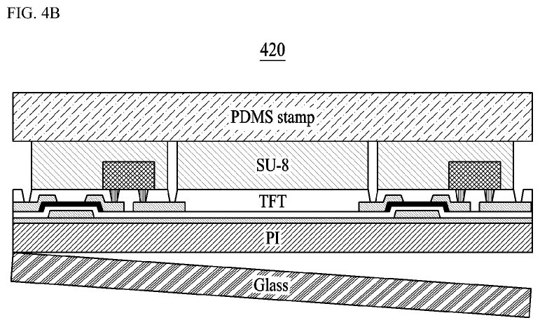

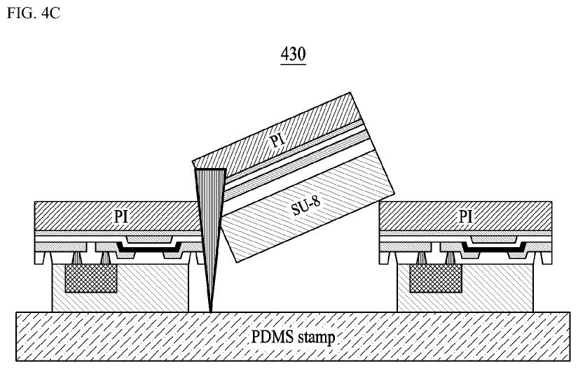

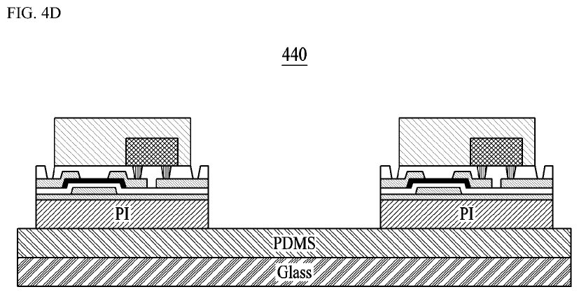

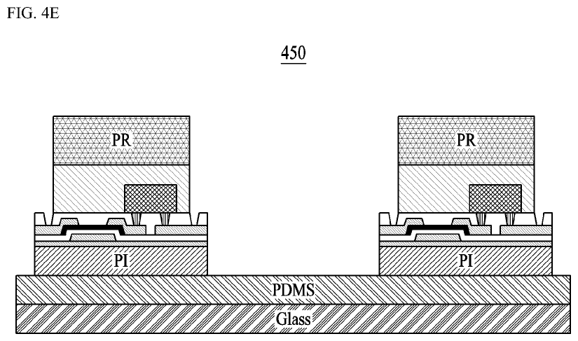

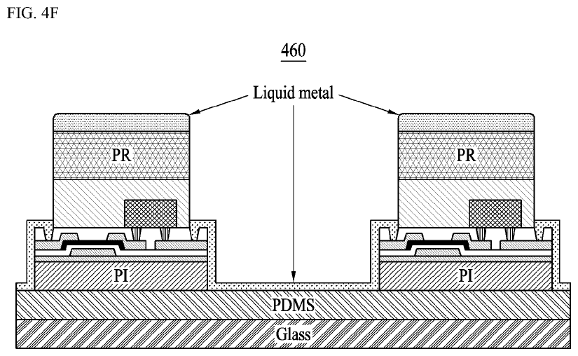

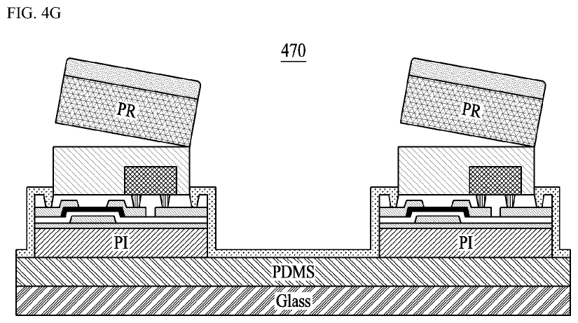

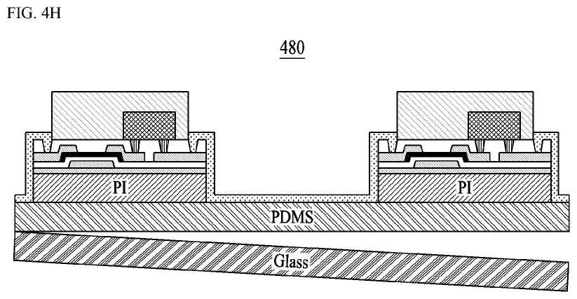

The method of manufacturing a stretchable display according to one embodiment will be described in more detail with reference to FIGS. 4A to 8.

FIGS. 4A to 4H are diagrams explaining the method of manufacturing a stretchable display according to one embodiment in more detail.

Referring to FIGS. 4A to 4H, according to the manufacturing method, in step 410, an LED-TFT structure may be formed on a first carrier substrate (e.g., glass substrate). Here, the LED-TFT structure may include a flexible substrate (e.g., PI substrate), at least one thin-film transistor (TFT), a micro-LED, and a passivation layer (e.g., SU-8) surrounding the micro-LED.

According to one aspect, according to the manufacturing method, in step 410, before forming the flexible substrate, the first carrier substrate may be coated with a solution-treated carbon nanotube (CNT)/graphene oxide (GO) layer to reduce the adhesion between the first carrier substrate and the flexible substrate. Through this process, the first carrier substrate may be separated using a non-laser method.

Next, according to the manufacturing method, in step 420, after attaching a polymer stamp (e.g., PDMS stamp) on the upper portion of the LED-TFT structure, i.e., on the passivation layer, the first carrier substrate may be separated.

For example, according to the manufacturing method, in step 420, the first carrier substrate may be separated from the LED-TFT structure attached to the polymer stamp using a mechanical method (i.e., non-laser method).

Next, according to the manufacturing method, in step 430, based on a laser cutting process, the LED-TFT structure may be cut into single pixel units, and an area where the thin-film transistor (TFT) is not formed may be removed. Through this process, a plurality of pixel islands may be formed.

For example, according to the manufacturing method, in step 430, the inverted LED-TFT structure attached to the polymer stamp may be cut at 1.5 mm intervals using a green laser to form an aligned 4×4 pixel array (i.e., 16 pixel islands).

Next, according to the manufacturing method, in step 440, a plurality of pixel islands attached to the polymer stamp may be transferred onto the stretchable substrate (e.g., PDMS substrate). At this time, the stretchable substrate may be attached to a second carrier substrate (e.g., glass substrate).

Next, according to the manufacturing method, in step 450, negative PR may be applied onto a preset area of the stretchable substrate where the pixel islands have been transferred.

Next, according to the manufacturing method, in step 460, a liquid metal may be applied onto the stretchable substrate coated with the negative PR.

Next, according to the manufacturing method, in step 470, the negative PR may be removed to form a plurality of pixel wires connecting adjacent pixel islands of the pixel islands and a plurality of bus wires connected to at least one pixel island of the pixel islands.

That is, according to the manufacturing method, in steps 450 to 470, through a lift-off process based on negative PR, a plurality of pixel wires and a plurality of bus wires may be formed.

For example, according to the manufacturing method, in step 470, through a lift-off process in which an acetone solution is sprayed, the negative PR may be removed to form the pixel wires and the bus wires.

Next, according to the manufacturing method, in step 480, the pixel islands and the stretchable substrate on which the pixel islands and the bus wires are formed may be separated from the second carrier substrate.

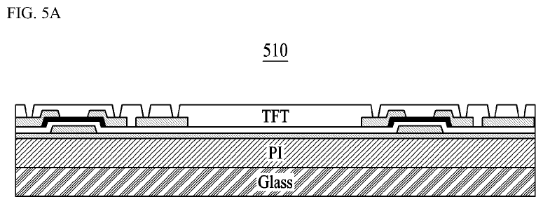

FIGS. 5A to 5D are diagrams explaining a method of forming an LED-TFT structure in the method of manufacturing a stretchable display according to one embodiment in more detail.

Referring to FIGS. 5A to 5D, according to the manufacturing method, in step 510, a flexible substrate (e.g., PI substrate) and at least one thin-film transistor (TFT) may be formed on a first carrier substrate (e.g., glass substrate).

For example, the at least one thin-film transistor (TFT) may include two thin-film transistors (i.e., switching TFT and reset TFT) and one ferroelectric thin-film transistor (FeTFT) including a ferroelectric material based on zirconium (Zr) for driving (i.e., 2TFT+1FeTFT structure).

For example, according to the manufacturing method, in step 510, the first carrier substrate may be coated with a carbon nanotube (CNT)/graphene oxide (GO) layer, the carbon nanotube (CNT)/graphene oxide (GO) layer may be spin-coated to a thickness of 10 μm with PI, and then curing may be performed at 450° C. for 1 hour to form a flexible substrate.

For example, according to the manufacturing method, in step 510, after depositing a silicon oxide (SiO₂) buffer layer with a thickness of 300 nm through plasma enhanced chemical vapor deposition (PECVD), a molybdenum (Mo) layer with a thickness of 120 nm may be deposited by sputtering, and patterning may be performed to form the gate electrode of the thin-film transistor.

In addition, according to the manufacturing method, in step 510, after depositing a double layer of SiNₓ (100 nm) and SiO₂ (130 nm) as a gate insulating layer through PECVD, an a-IGZO layer with a thickness of 30 nm may be deposited. Here, the a-IGZO layer may be deposited through reactive sputtering using a polycrystalline IGZO target with a composition of InO₃:Ga₂O₃:ZnO=1:1:1 mol %.

In addition, according to the manufacturing method, in step 510, source and drain electrodes may be formed by depositing and pattering a 150 nm thick Mo layer of the thin-film transistor, a silicon oxide (SiO₂) layer with a thickness of 150 nm may be deposited as the passivation layer of the thin-film transistor using PECVD, and then annealing may be performed at 250° C. for 4 hours under vacuum conditions to form the thin-film transistor.

Next, according to the manufacturing method, in step 520, solder may be formed on at least one thin-film transistor (TFT). Here, the solder may be formed at a location corresponding to at least one of the source and drain electrodes of the thin-film transistor (TFT) to electrically connect the thin-film transistor (TFT) and the micro-LED. For example, the solder may include SnAgCu (SAC) and may be patterned through a lift-off process.

Next, according to the manufacturing method, in step 530, to improve bonding quality and remove the oxide layer of the solder (i.e., SAC solder), the micro-LED may be bonded to the thin-film transistor after coating the entire layer with flux.

For example, according to the manufacturing method, in step 530, the flux may be formed by spin-coating a substrate surface (i.e., backplane) on which the thin-film transistor is formed with a flux material.

In addition, according to the manufacturing method, in step 530, the micro-LED and the thin-film transistor may be bonded through a pick and place method based on a polymer stamp.

As a more specific example, according to the manufacturing method, in step 530, after placing the micro-LED on the solder using a PDMS stamp, bonding may be performed at a temperature of 250° C. for 2 minutes.

Next, according to the manufacturing method, in step 540, after removing the flux existing in areas other than the junction area of the thin-film transistor, a passivation layer (e.g., SU-8) may be formed to prevent damage to the micro-LED due to external shock.

For example, according to the manufacturing method, in step 540, the flux may be removed by performing oxygen (O₂) plasma treatment at 100 W for 5 minutes.

In addition, according to the manufacturing method, in step 540, after fixing the micro-LED by performing spin coating with the passivation layer, a contact pad area may be opened to ensure ease of connection with liquid metal-based wires.

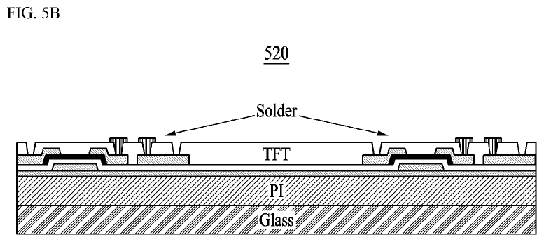

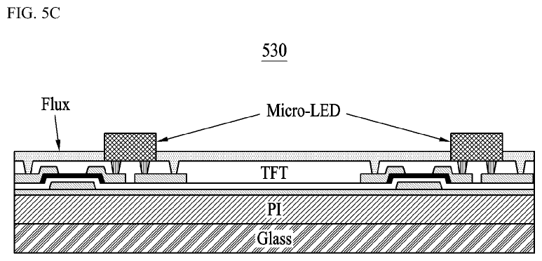

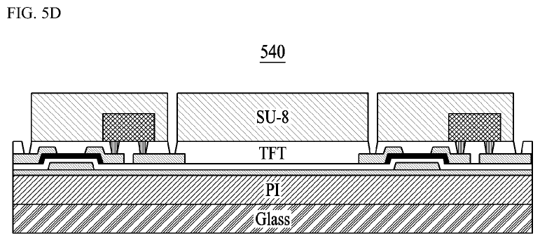

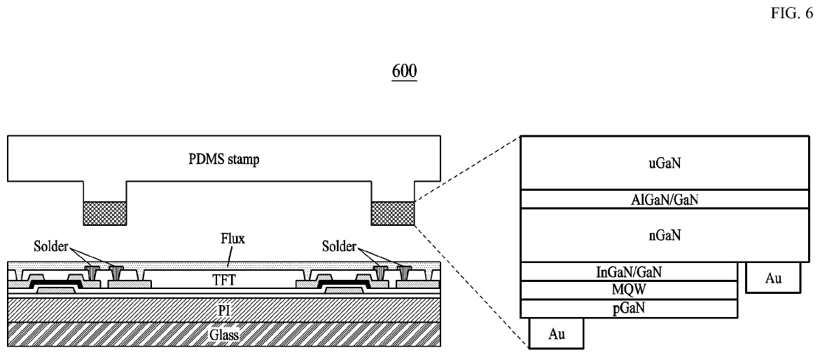

FIG. 6 is a diagram explaining the structural features of the micro-LED element of the stretchable display according to one embodiment in more detail.

Referring to FIG. 6, each of a plurality of pixel islands of the stretchable display according to one embodiment may include a micro-LED. Here, the micro-LED may include a plurality of electrodes (i.e., n-type electrode and p-type electrode) based on a uGaN layer, an AlGaN/GaN layer, an nGaN layer, an InGaN/GaN layer, a multi quantum well (MQW) layer, a pGaN layer, and gold (Au).

In addition, among the electrodes of the micro-LED, at least one electrode may be connected to at least one of the source and drain electrodes of a thin-film transistor through solder.

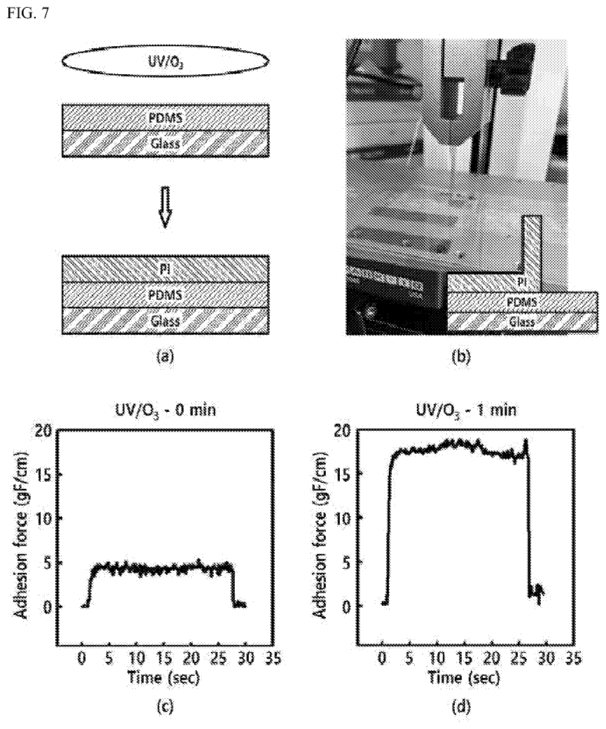

FIG. 7 includes diagrams explaining an ozone (O₃) treatment method in the method of manufacturing a stretchable display according to one embodiment in more detail.

Referring to FIG. 7, FIG. 7A shows the process of UV/O₃ plasma treatment of a stretchable substrate (PDMS substrate), and FIG. 7B shows the 90° peeling test process of a flexible substrate to measure adhesion between the stretchable substrate (PDMS substrate) and the flexible substrate (PI substrate).

In addition, FIG. 7C shows the peeling test results when UV/O₃ plasma treatment is not performed, and FIG. 7D shows the peeling test results when UV/O₃ plasma treatment is performed for 1 minute.

Referring to FIG. 7A, according to the manufacturing method according to one embodiment, a flexible substrate (PI substrate) provided in each of a plurality of pixel islands may be bonded onto a stretchable substrate (PDMS substrate). At this time, the stretchable substrate (PDMS substrate) may be subjected to UV/O₃ plasma treatment for 1 to 5 minutes to improve the adhesion between the stretchable substrate (PDMS substrate) and the flexible substrate (PI substrate).

As shown in FIGS. 7B to 7D, when UV/O₃ plasma treatment is not performed, the adhesion between the stretchable substrate (PDMS substrate) and the flexible substrate (PI substrate) is 5 gF/cm. When UV/O₃ plasma treatment is performed for 1 minute, the adhesion is increased to 18 gF/cm.

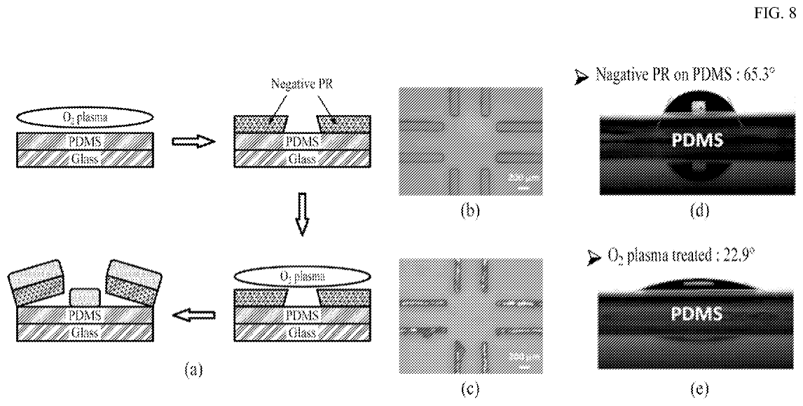

FIG. 8 includes diagrams explaining an oxygen (O₂) plasma treatment method in the method of manufacturing a stretchable display according to one embodiment in more detail.

Referring to FIG. 8, FIG. 8A shows the process of performing oxygen (O₂) plasma treatment, FIGS. 8B and 8C show an optical image after negative PR development and an optical image after negative PR removal, respectively, and FIGS. 8D and 8E show the contact angle measurement results of the stretchable substrate (PDMS substrate) before and after oxygen (O₂) plasma treatment, respectively.

Referring to FIGS. 8A to 8C, according to the manufacturing method according to one embodiment, after performing oxygen (O₂) plasma treatment on the stretchable substrate (PDMS substrate) at 30 W for 5 seconds, a plurality of pixel islands may be transferred to the stretchable substrate (PDMS substrate).

In addition, according to the manufacturing method according to one embodiment, to improve the wettability of a liquid metal on the stretchable substrate (PDMS substrate) after forming negative PR, the stretchable substrate (PDMS substrate) may be subjected to oxygen (O₂) plasma treatment at 50 W for 30 seconds.

That is, according to the manufacturing method according to one embodiment, the hydrophobic properties of the PDMS substrate may be changed to hydrophilic properties through oxygen (O₂) plasma treatment. Through this process, the adhesion between the PDMS substrate and the negative PR may be improved.

Referring to FIGS. 8D and 8E, the contact angle of negative PR for a PDMS substrate without oxygen (O₂) plasma treatment is 65.3°. The contact angle of negative PR for a PDMS substrate subjected to oxygen (O₂) plasma treatment is reduced to 22.9°. These results confirm that the PDMS substrate acquires hydrophilic properties through oxygen (O₂) plasma treatment.

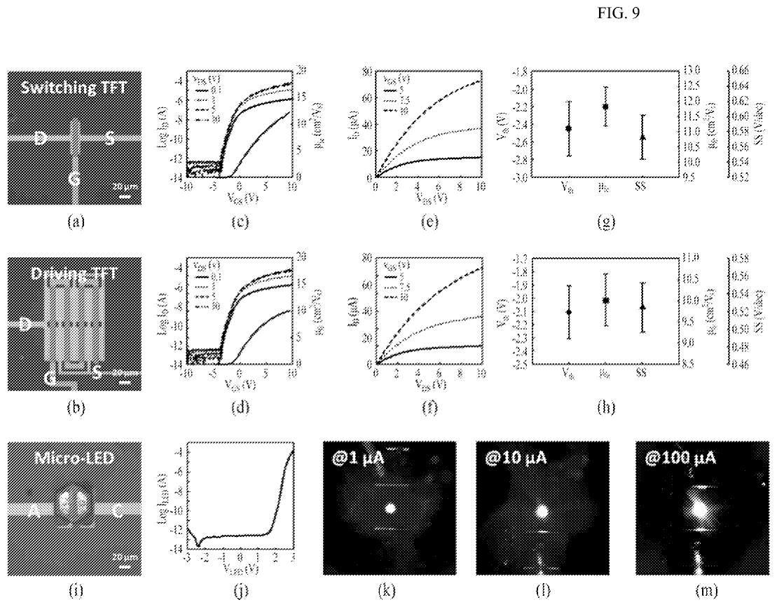

FIGS. 9A to 9M include diagrams explaining the performance experiment results of the thin-film transistor and micro-LED of the stretchable display according to one embodiment.

FIGS. 9A and 9B show optical images of a switching thin-film transistor (channel width/length=55/6 μm) and a driving thin-film transistor (channel width/length=440/6 μm) provided in a pixel island, respectively.

In addition, FIGS. 9C and 9D show the transfer characteristics of the switching thin-film transistor and the driving thin-film transistor when a drain-source voltage (V_{DS}) is 0.1V, 1V, 5V, or 10 V, respectively. FIGS. 9E and 9F show the output characteristics of the switching thin-film transistor and the driving thin-film transistor when a gate-source voltage (V_{GS}) is 5V, 7.5V, or 10 V, respectively. FIGS. 9G and 9H show the measurement results of the threshold voltages (Vₜₕ), field effect mobility (μ_{fe}), and subthreshold swing (SS) characteristics of 16 switching thin-film transistors and 16 driving thin-film transistors.

In addition, FIG. 9I shows an optical image of a micro-LED provided in a pixel island, FIG. 9J shows the electrical properties of the micro-LED, and FIGS. 9K, 9L, and 9M show micro-LEDs driven at constant currents of 1 μA, 10 μA, and 100 μA, respectively.

As shown in FIGS. 9A to 9H, the threshold voltage (Vₜₕ), field effect mobility (μ_{fe}), and SS values of the switching thin-film transistor and the driving thin-film transistor (i.e., switching thin-film transistor/driving thin-film transistor) are −2.4/−2.0 V, 12.3/10.1 cm^{2 V-1}s⁻¹, and 0.54/0.51 V dec⁻¹, respectively.

The oxide thin-film transistor exhibits a very low off-state drain current of less than 1 pA at a high V_{DS} of 10 V, and each pixel appears completely off at V_{GS}<−5 V.

In an AM display pixel circuit, the brightness of the micro-LED may be controlled by driving a thin-film transistor with a gate bias where the driving thin-film transistor and the micro-LED are connected in series, so the channel width/length of the driving thin-film transistor must be designed carefully. Through optimized design (channel width/length=440/6 μm), the driving thin-film transistor may reach 546 μA at V_{DS}=10 V and V_{GS}=10 V.

In addition, to ensure uniformity, after the process, the threshold voltage (Vₜₕ), field effect mobility (μ_{fe}), and SS values of 16 switching thin-film transistors and 16 driving thin-film transistors (i.e., switching thin-film transistor/driving thin-film transistor) provided in each of the 4×4 pixel islands were measured. The results were −2.45±0.31/−2.11±0.20 V, 11.8±0.6/10.0±0.6 cm² V⁻¹s⁻¹, and 0.57±0.03/0.52±0.03 Vdec⁻¹.

That is, despite the integrated design of the micro-LED and the liquid metal-based wire, it can be confirmed that the oxide thin-film transistor shows uniform electrical properties.

Referring to FIGS. 9I to 9M, since the stretchable display according to one embodiment uses a GaN-based flip-chip micro-LED, the stretchable display has an advantage in terms of process compared to a vertical LED, which requires an additional connection process to a top electrode after bonding. At this time, the micro-LED may be designed with a size of 60×52 μm² and a thickness of 8 μm, and the gold (Au) anode/cathode electrodes of the micro-LED may be bonded to flux/solder metal.

In addition, the micro-LED exhibits an on-state current of 216 μA at a voltage of 3 V and emits blue light under various constant currents of 1 μA, 10 μA, and 100 μA.

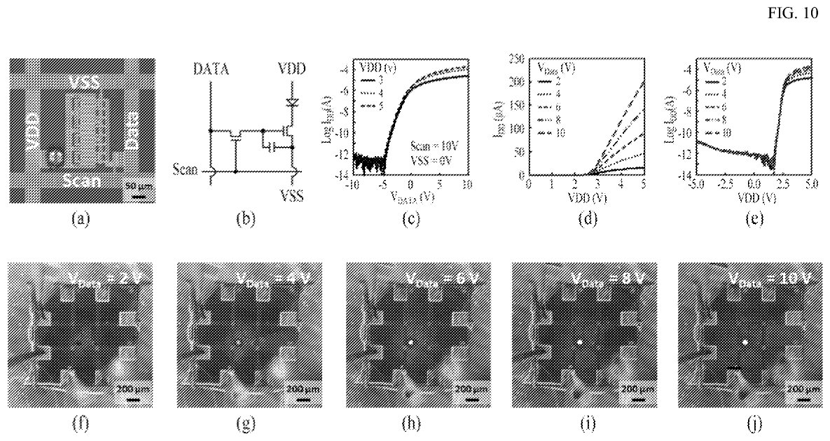

FIGS. 10A to 10J include diagrams explaining the pixel performance experiment results of the stretchable display according to one embodiment.

FIGS. 10A and 10B show an optical image and circuit diagram of a unit pixel consisting of the switching thin-film transistor, the driving thin-film transistor, and the micro-LED, respectively. FIG. 10C shows the results of measuring the transfer characteristics of the series-connected micro-LED and driving thin-film transistor by sweeping V_{Data} from −10 V to 10 V when V_{DD} is 3V, 4 V and 5V.

In addition, FIGS. 10D and 10E show the results of measuring the transfer characteristics of the series-connected micro-LED and driving thin-film transistor at a linear log scale (FIG. 10D) and a logarithmic scale of unit pixels (FIG. 10E) by sweeping V_{DD} from −5V to 5V when V_{Data} is 2 V, 4 V, 6 V, 8 V, and 10 V. FIGS. 10F to 10J show micro-LEDs driven when V_{Data} is 2 V, 4 V, 6 V, 8 V, and 10 V.

Referring to FIGS. 10A and 10B, in the stretchable display according to one embodiment, a molybdenum (Mo)-based mesh electrode with a width of 5 μm and a gap of 5 μm may be used to prevent unpredictable metal cracks from occurring due to mechanical deformation.

Specifically, cracks in a metal as an active layer may significantly reduce the electrical performance of existing TFTs, but a metal mesh electrode with a narrow unit width may improve the flexibility of a thin-film transistor on a flexible substrate (PI substrate).

In addition, since a storage capacitor with the existing MIM structure may be easily damaged and a short circuit may be caused between MIM stacks, a ferroelectric thin-film transistor may be applied between a source and a gate in a driving TFT. In this case, the storage capacitor may be replaced with the ferroelectric thin-film transistor.

Referring to FIGS. 10C to 10J, the switching thin-film transistor may be turned on/off by a scan signal of 10 V/−10 V. When the switching thin-film transistor is turned on, a data voltage (V_{Data}) may be applied to the gate electrode of the driving thin-film transistor, and the brightness of the micro-LED may be controlled by V_{DD} and V_{SS} values.

In addition, it is confirmed that blue light emission and current increase in a micro-LED (I_{DD}) depending on V_{DD}. Here, I_{DD} may be controlled by V_{Data} corresponding to the I_{DD}, which is the intersection between the output characteristics of the I_{LED} and the thin-film transistor.

Specifically, I_{DD} values of 15.9 μA, 46.1 μA, 89.5 μA, 143.0 μA, and 203.5 μA may be achieved by adjusting V_{data} to 2 V, 4 V, 6 V, 8 V, and 10 V, respectively. Through this, it can be confirmed that the brightness of the micro-LED may be adjusted by controlling V_{data}, and as a result, it can be confirmed that the pixel island shows good and uniform electrical properties.

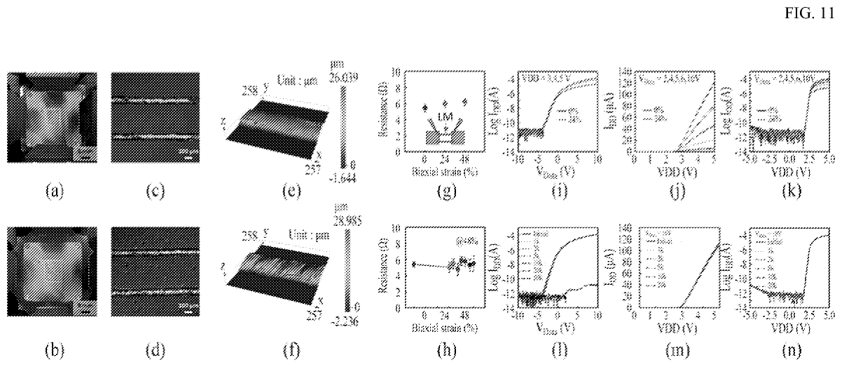

FIGS. 11A to 11N include diagrams explaining the experimental results of changes in electrical characteristics depending on the shapes of the liquid metal-based wire and pixel island of the stretchable display according to one embodiment.

FIGS. 11A to 11F show 2D and 3D optical images (laser confocal images) of pixel islands connected by liquid metal-based wires in the initial state (FIGS. 11A, 11C, and 11E) and the 24% biaxially stretched state (FIGS. 11B, 11D, and 11F).

FIG. 11G shows the measurement results of resistance changes of 16 liquid metal-based wires interconnecting pixel islands under biaxial stretching. Here, the width/length of the liquid metal-based wire in the initial state is 100 μm/2000 μm. To achieve a biaxial stretching state of 24%, a liquid metal-based wire may be expanded up to 48% based on a rigid flexible substrate (PI substrate) with the same dimensions.

In addition, FIG. 11H shows the measurement results of the electrical properties of a liquid metal-based wire under a stretchable substrate (PDMS substrate) that repeated biaxial stretching and relaxation for 100,000 cycles.

In addition, FIGS. 11I to 11K and FIGS. 11L to 11N show the measurement results of the transfer characteristics and output characteristics of unit pixel (FIGS. 11I and 11L), linear (FIGS. 10J and 10M), and log (FIGS. 10K and 10N)) scales.

Referring to FIGS. 10A and 10B, the pixel island according to one embodiment was manufactured by applying a liquid metal-based wire on a stretchable substrate (PDMS substrate) and characterized in biaxial stretching and relaxation states. The adhesion between the flexible substrate (PI substrate) and the stretchable substrate (PDMS substrate) may be improved by UV/O₃ treatment and the wettability of the stretchable substrate (PDMS substrate) may be improved by O₂ plasma treatment, resulting in maintaining the shapes of pixel islands and liquid metal-based wires. Specifically, it was found that the shape was maintained without distortion or damage even at 24% biaxial elongation.

FIGS. 11C and 11F, according to the 2D and 3D image profiles of liquid metal-based wires placed on a stretchable substrate (PDMS substrate) in relaxed and contracted states, the width and spacing of the liquid metal-based wires in the relaxed state are 100 μm and 400 μm, respectively.

Referring to FIG. 11G, the biaxially stretched liquid metal-based wires have a rough surface and a height that varies depending on locations, ranging from 16 μm to 20 μm. The change in resistance of the wires due to elongation is an important factor because it may affect the brightness of micro-LEDs driven by current.

The stretchable display consists of a pixel island area of 1.5 mm and a gap between pixel islands of 1.5 mm. Since the pixel island cannot be stretched, only the LM area of PDMS must be stretched. Accordingly, in a display stretched by 24%, the expanded size of one pixel is 3.72×3.72 mm² (relaxed state, 3×3 mm²), the effective expansion area requires a gap of 2.22 mm (relaxed state, a gap of 1.5 mm), and liquid metal-based wires elongate by 48%.

In addition, the average resistances of the liquid metal-based wires are 5.4Ω (relaxed), 5.9Ω (24%), and 6.2Ω (48%), which means that the resistance of the display stretched by 24% increases by 14%.

Referring to FIG. 11H, as a result of performing repetitive biaxial stretching of 24% for 100,000 cycles using 16 liquid metal-based wires, the initial average resistance of the liquid metal-based wires was 5.4Ω, and even after 100,000 cycles, the initial average resistance was 5.5Ω, showing that the degree of deformation was small enough to be ignored.

Referring to FIGS. 11I and 11J, even on the 24% biaxially stretched stretchable substrate (PDMS substrate), the electrical properties of the micro-LED exhibit stable performance according to changes in V_{DD} and V_{Data}.

This stability may be achieved by the robust PI substrate and the SU-8 passivation layer. Specifically, the typical Young's moduli of PDMS (base/curing agent: 20/1), PI, and SU-8 are 0.445 MPa, 2.5 GPa, and 2.0 GPa. At V_{Data}=2 V, 4 V, 6 V, 8 V, and 10 V and V_{DD}=5 V, the I_{DD} ratios (24% stretched/relaxed state) are 5.9% (5.93 μA/5.60 μA), 3.5% (21.24 μA/20.53 μA), 2.4% (46.70 μA/45.60 μA), 1.8% (81.21 μA/79.77 μA), and 1.4% (123.95 μA/122.24 μA), respectively.

Referring to FIGS. 11I and 11K, through stable off-state current changes according to changes in V_{DD} and V_{Data}, the stability of the robust a-IGZO TFT and micro-LED may be confirmed in the biaxially stretched state.

Referring to FIGS. 11L to 11N, I_{DD} decreases with the stretching cycle and rapidly decreases to 10 pA at 50,000 cycles. Typically, accumulated tensile stress induces a negative threshold voltage (Vₜₕ) shift in a thin-film transistor, but a micro-LED of a backplane may be damaged due to the biaxial stretching cycle.

However, as a result of an experiment on the stretchable display according to one embodiment, it was confirmed that the decrease in on-state I_{DD} due to changes in V_{DD} and V_{Data} was minimal. Specifically, I_{DD} ratios (20,000 cycles/initial state) in each of V_{Data}=2 V, 4 V, 6 V, 8 V, and 10 V (V_{DD}=5V) were −5.0% (4.00 μA/4.21 μA), −4.3% (16.69 μA/17.45 μA), −3.7% (39.44 μA/40.95 μA), −3.3% (71.38 μA/73.79 μA), and −3.3% (111.14 μA/114.99 μA).

According to one embodiment, the present disclosure can minimize the occurrence of cracks and damage due to deformation of wiring by applying a stretchable wire based on a liquid metal that is not curved.

According to one embodiment, the present disclosure can secure excellent electrical characteristics by integrating pixel islands and liquid metal-based wires on a stretchable substrate.

According to one embodiment, the present disclosure can minimize an area and ensure operational stability by replacing a capacitor provided in each pixel island with a ferroelectric thin-film transistor.

Although the present disclosure has been described with reference to limited embodiments and drawings, it should be understood by those skilled in the art that various changes and modifications may be made therein. For example, the described techniques may be performed in a different order than the described methods, and/or components of the described systems, structures, devices, circuits, etc., may be combined in a manner that is different from the described method, or appropriate results may be achieved even if replaced by other components or equivalents.

Therefore, other embodiments, other examples, and equivalents to the claims are within the scope of the following claims.

[Description of Symbols]

| | |
|---|---|
| 200: | STRETCHABLE DISPLAY |
| 210: | STRETCHABLE SUBSTRATE |
| 220: | PIXEL ISLAND |
| 220-1: | FLEXIBLE SUBSTRATE |
| 220-2: | THIN-FILM TRANSISTOR |
| 220-3: | MICRO-LED |
| 230: | PIXEL WIRES |
| 240: | BUS WIRES |

What is claimed is:

1. A stretchable display, comprising:
a stretchable substrate;
a plurality of pixel islands formed on the stretchable substrate, wherein each of the pixel islands comprises at least one thin-film transistor and one micro-LED;
a plurality of pixel wires formed based on a liquid metal and connecting adjacent pixel islands among the pixel islands to each other; and
a plurality of bus wires formed based on the liquid metal and connected to at least one pixel island among the pixel islands.

2. The stretchable display according to claim 1, wherein each of the bus wires is connected to the at least one pixel island through one end thereof and is connected to a pixel driving circuit through the other end thereof.

3. The stretchable display according to claim 1, wherein, in each of the pixel islands, the thin-film transistor and the micro-LED are bonded through solder and flux formed on the thin-film transistor.

4. The stretchable display according to claim 1, wherein the pixel islands are formed on the stretchable substrate based on a transfer process and a laser cutting process using a stamp for the thin-film transistor and micro-LED formed on a flexible substrate.

5. The stretchable display according to claim 1, wherein the pixel wires and the bus wires are formed on the stretchable substrate through a lift-off process based on negative PR.

6. The stretchable display according to claim 1, wherein each of the pixel islands comprises two thin-film transistors and one ferroelectric thin-film transistor.

7. A method of manufacturing a stretchable display, comprising:
transferring a plurality of pixel islands each comprising at least one thin-film transistor and one micro-LED onto a stretchable substrate;
applying negative PR onto a preset area of the stretchable substrate where the pixel islands have been transferred;
applying a liquid metal onto the stretchable substrate coated with the negative PR; and
removing the negative PR to form a plurality of pixel wires connecting adjacent pixel islands among the pixel islands to each other and a plurality of bus wires connected to at least one pixel island among the pixel islands.

8. The method according to claim 7, wherein the transferring further comprises forming an LED-TFT structure comprising a flexible substrate, the thin-film transistor, and the micro-LED on a carrier substrate;
attaching a polymer stamp to an upper portion of the LED-TFT structure and separating the LED-TFT structure from the carrier substrate;
forming the pixel islands by performing a laser cutting process on the LED-TFT structure attached to the polymer stamp; and
transferring the pixel islands attached to the polymer stamp onto the stretchable substrate.

9. The method according to claim 8, wherein, in the forming of the LED-TFT structure, after forming a coating layer based on carbon nanotubes (CNTs) and graphene oxide on the carrier substrate, the flexible substrate is bonded to the coating layer.

10. The method according to claim 8, wherein the forming of the LED-TFT structure further comprises depositing solder on the thin-film transistor;
coating the solder-deposited thin-film transistor with flux;
bonding the micro-LED;
removing the flux; and
forming a passivation layer.

11. The method according to claim 7, wherein the transferring further comprises treating the stretchable substrate with ultraviolet rays (UV) and ozone (O₃); and
transferring the pixel islands onto the stretchable substrate treated with ultraviolet rays (UV) and ozone (O₃).

12. The method according to claim 7, wherein, in the applying of the liquid metal, after treating the stretchable substrate coated with the negative PR with oxygen (O₂) plasma, the liquid metal is applied.
